(19) United States
(12) Patent Application Publication
(10) Pub. No.: US 2022/0224209 A1
(43) Pub. Date: Jul. 14, 2022

(54) ELECTRIC MOTOR WITH INJECTION MOULDED STATOR

(71) Applicant: Nidec Corporation, Kyoto (JP)

(72) Inventor: Pascual GUARDIOLA, Ingersheim (DE)

(21) Appl. No.: 17/570,421

(22) Filed: Jan. 7, 2022

(30) Foreign Application Priority Data
Jan. 11, 2021 (DE) 102021100305.9

(51) Int. Cl. H02K 15/02; H02K 5/22; H05K 3/32; H02K 3/28

(52) U.S. Cl. CPC H02K 15/02; H02K 5/225; H02K 2211/03; H02K 3/28; H05K 3/32

(57) ABSTRACT

An electric motor includes a printed circuit board, a rotor which is mounted rotatably about an axis of rotation, and a stator circumferentially surrounded by the rotor. The stator includes stator teeth and coils wound around the stator teeth, the coils being made from a winding wire with winding wire ends. The stator is overmolded by an injection molding, and a plug assembly is made on an upper side of the stator by the injection molding. The plug assembly includes contacts overmolded by the injection molding and defining a plug connection of an external power supply connection on one side and making direct electrical contact with the printed circuit board on another side.

### CROSS REFERENCE TO RELATED APPLICATION

The present application claims priority under 35 U.S.C. § 119 to German Application No. 10 2020 100 305.9, filed on Jan. 11, 2021, the entire contents of which are hereby incorporated herein by reference.

### 1. FIELD OF THE INVENTION

The present disclosure relates to an electric motor, and to a method of electrically contacting a stator to a printed circuit board.

### 2. BACKGROUND

Brushless DC motors of the type relevant here are referred to as external rotor motors and have a rotor that is connected to a motor shaft and is rotatably mounted in a housing. The rotor is provided with permanent magnets. Inside the rotor is a stator which carries a number of windings on an iron core. When suitably controlled, the windings generate a magnetic field which drives the rotor to rotate. The windings are usually wound in three phases and are accordingly provided with three electrical connections via which the windings can be connected to a controller (ECU).

For the purpose of the geometrical description of the electric motor, the axis of rotation of the motor is assumed to be the central axis and the axis of symmetry. The stator is arranged concentrically with the axis of rotation and the rotor. The axis of rotation simultaneously defines an axial direction in which the thickness of the stator pack and the axial length of the motor are specified. Moreover, with respect to the central axis, a radial direction indicates the distance from the central axis, and a circumferential direction is defined tangentially to a certain radius arranged in the radial direction. The connection side of the stator, where the winding wires are connected to the controller, is described as the top side of the stator.

The controller is connected to an external power connection. Usually, additional components are required for this.

### SUMMARY

Example embodiments of the present disclosure provide electric motors with an assembly process that is as automated and inexpensive as possible, in which the energization of the controller is compact and simple.

An electric motor according to an example embodiment of the present disclosure includes a rotor which is mounted rotatably about an axis of rotation and which circumferentially surrounds a stator. The stator includes stator teeth and coils wound around the stator teeth. The coils are made of a winding wire including winding wire ends. The electric motor further includes a printed circuit board. The stator is overmolded by an injection molding. A connector assembly is co-formed on an upper side of the stator by the injection molding, and includes contacts overmolded by injection molding to define a connector connection of an external power supply connection on one side and to directly electrically contact the printed circuit board on another side. By providing the connector assembly when the stator is overmolded, there is no need for additional components. By providing the connector assembly in the injection molding, efficiency of the motor is increased because higher thermal conductivity is present. In addition, the connection to the printed circuit board is particularly simple. For this purpose, the printed circuit board preferably includes penetrating recesses, in each of which a free end of the contacts engages.

It is advantageous for the assembly process if the contacts are rectangular or approximately rectangular and extend in a radial direction to the longitudinal axis and parallel or approximately thereto.

For connection to an external power supply connector, the contacts preferably project radially beyond the stator and protrude radially from an overmolded region to define the connector connection.

The connector assembly may thus be arranged to supply current to the controller.

Other free ends of the contacts preferably project upwardly from the overmolded region and contact the printed circuit board, the free ends including a shoulder to axially limit a depth of insertion into the circuit board.

It is preferable that receptacles are additionally provided on the upper side of the stator in the injection molding process, into which at least one winding wire end and an insulation displacement contact are inserted, the insulation displacement contact making electrical contact with the at least one winding wire end and including a plug-in pin which makes direct electrical contact with the printed circuit board. By defining the receptacles in the injection molding, efficiency is increased because higher thermal conductivity is present.

The stator is preferably completely overmolded on the upper side and a lower side, and at least partially overmolded in a circumferential surface.

Since the insulation displacement contact is already attached to the stator during assembly and includes a plug-in pin, the stator can be contacted electrically easily and without taking up much space on the printed circuit board. In addition, the manufacturing costs are low, as no additional components are required.

It is preferably provided that in a region of magnets, the stator is not overmolded and includes recesses to increase the power transmission of the electric motor.

Preferably, the printed circuit board includes recesses into which a plug-in pin engages. This makes contacting particularly easy.

The winding wire ends are preferably bent outwards in the radial direction and each inserted into a respective one of the receptacles. The receptacles are thus located on the outside of the stator surface in the radial direction, making them easily accessible.

In an example embodiment, the receptacles extend with their longitudinal axes parallel or substantially parallel to the longitudinal axis of the stator, are pocket-shaped and rectangular or substantially rectangular in cross-section with two longitudinal sides and two transverse sides, each of the receptacles including an opening which is located on one of the two longitudinal sides and two transverse sides remote from the stator. The two longitudinal sides extend tangentially, in a circumferential direction of the longitudinal axis of the stator. On an end surface remote from the stator, the receptacles each include, on the inner longitudinal side, an incision which extends parallel or substantially parallel to the longitudinal axis of the stator and into which the at least one winding wire end is inserted. Such receptacles are particularly easy to form by injection molding. In addition, they can accommodate the insulation displacement contacts in a secure and defined manner.

The receptacles are preferably evenly spaced from one another in a circumferential direction, with a total of three being provided, all of which extend over an angular range of less than 120°. Due to the spacing, it is possible to separately guide the wires of the individual phases. However, since the spacing is small, pressing in into the printed circuit board is simplified.

The electric motor preferably includes three phase groups, each of the phase groups including two winding wire ends which are inserted into a common one of the receptacles and which are electrically contacted by a common one of the insulation displacement contacts.

It is advantageous if the electric motor has 10 poles and 12 stator teeth, for example.

It is preferably provided that the winding wire ends are held on the upper side of the stator by a wire holder which is overmolded in the injection molding process, so that the position of the wire holder is secured.

The injection molding process is preferably carried out with plastic or resin.

Furthermore, an electric pump with a previously described electric motor is provided.

An example embodiment of a method of electrically contacting a stator of an electric motor with a printed circuit board is provided. The stator includes stator teeth and coils wound on the stator teeth, the coils are made from a winding wire including winding wire ends and the winding wire ends extend parallel or substantially parallel to the longitudinal axis of the stator. The method includes overmolding the stator to form a connector assembly on a top surface of the stator, the connector assembly including overmolded contacts each including a first free end and a second free end, positioning the stator with respect to the printed circuit board, the printed circuit board and the stator being aligned with their upper and lower sides parallel or substantially parallel to each other and the longitudinal axes congruent, simultaneously pressing the first free ends of the contacts into recesses of the printed circuit board in the longitudinal direction, and contacting an external power supply terminal with the second free ends of the contacts for energizing a controller on the printed circuit board.

This process is particularly simple and cost-effective.

Preferably, in the overmolding, the receptacles are additionally formed on the upper surface of the stator during overmolding of the stator, the method further including bending of the winding wire ends in a radial direction to the longitudinal axis of the stator to an outside and insertion into the receptacles, and inserting one insulation displacement contact in each case into one receptacle to make electrical contact between the winding wire ends and the insulation displacement contacts, each of the insulation displacement contacts including a plug-in pin, and then, the plug-in pins of the insulation displacement contacts are pressed into recesses in the printed circuit board in the longitudinal direction to make electrical contact between the printed circuit board and the winding wires.

In an assembly step, the winding wire ends are contacted with the printed circuit board and a connector assembly is connected to the printed circuit board, which allows current to be supplied to the controller located on the printed circuit board.

Preferably, an electric motor according to an example embodiment of the present disclosure may have any of the above features.

The above and other elements, features, steps, characteristics and advantages of the present disclosure will become more apparent from the following detailed description of the example embodiments with reference to the attached drawings.

### BRIEF DESCRIPTION OF THE DRAWINGS

Example embodiments of the present disclosure are explained in more detail below with reference to the drawings. Similar or similarly acting components are designated in the figures with the same reference signs.

FIG. 1 is a spatial view of a stator according to an example embodiment of the present disclosure.

FIG. 2 is a schematic diagram of the winding scheme of the stator of FIG. 1.

FIG. 3 is a sectional view of the stator of FIG. 1.

FIG. 4 is a spatial representation of an electric motor with the stator.

FIG. 5 is an illustration of the mounting of the stator on the printed circuit board.

### DETAILED DESCRIPTION

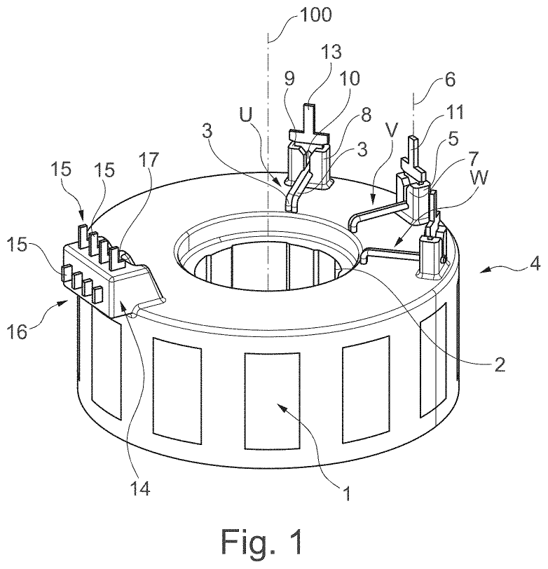

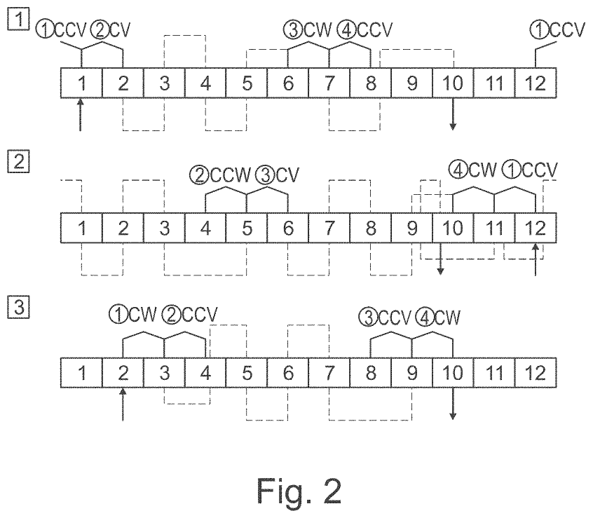

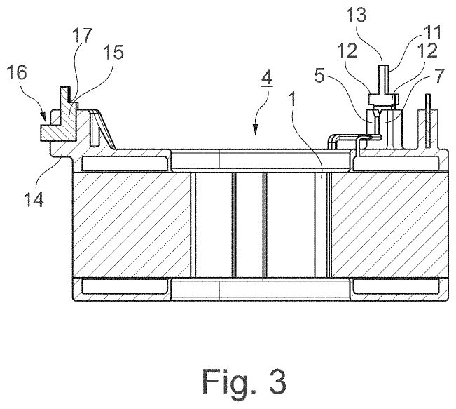

FIGS. 1 and 3 show a stator 1 extending coaxially with a longitudinal axis 100 and having a plurality of stator teeth, shown only schematically, around which respective coils, not shown, are wound. The stator teeth are arranged sequentially in the circumferential direction of the stator 1. The stator teeth are formed of laminations. The stator 1 is fixedly mounted within a housing of an electric motor, and is adapted to generate a time-varying magnetic field by the coils. A magnetized outer rotor, not shown, is thereby mounted within a central opening 2 of the stator 1. It is arranged to be rotated by an interaction with the time-varying magnetic field generated by the coils. A wire holder, not shown, is adapted to position the winding wire end portions of the wound coils of the stator 1. The wire holder is arranged on the upper side of the stator 1. In this regard, the coils are grouped into three phase groups U, V, W. For each phase group, two winding wire ends 3 are seen on the upper side of the stator 1. The exemplary electric motor has 10 poles and 12 stator teeth. The winding diagram is shown in FIG. 2.

The stator 1 with the wire holder is overmolded with plastic or resin in an injection molding process. The resulting stator unit 4 is shown in FIGS. 1 and 3. In the injection molding process, three receptacles 5 are also formed on the upper surface of the stator unit 4 with their longitudinal axes 6 extending parallel to the longitudinal axis 100. The receptacles 5 are pocket-shaped and substantially rectangular in cross-section, with two longitudinal sides 7 and two transverse sides 8. The openings of the pockets 9 are located on the side remote from the stator, at the top. The longitudinal sides 7 extend tangentially, in the circumferential direction of the longitudinal axis 100. On the end side remote from the stator, the receptacles 5 each have an incision 10 in the form of a slot on the inner longitudinal side 7. The slot 10 extends parallel to the longitudinal axis 100 and is provided for receiving the winding wire ends 3. The receptacles are evenly spaced from one another in the circumferential direction. All three together extend in total over an angular range of less than 120°. After the stator 1 has been overmolded by injection molding and the receptacles 5 have been formed, the winding wire ends 3 projecting from the end face of the stator unit are bent outward in the radial direction and inserted into the respective slot 10 of the receptacle 5. Thereafter, one insulation displacement contact (IDC) 11 is inserted into each receptacle 5 from above into the opening 9. The insulation displacement contact 11 has a clamping slot, not shown, into which one or more winding wire ends 3 can be received as required. When the insulation displacement contacts 11 are inserted into the pockets of the receptacles 5, the clamping slots are pushed onto the winding wire ends 3 lying in the receptacles and connected to the receptacles. By a sharp contact in the clamping slots, the insulation of the winding wire ends 3 is cut and an electrical contacting of the wire core of the winding wire is achieved. Adjacent to the clamping slot area, the insulation displacement contacts 11 have two projections 12 which limit the insertion path and which, in the inserted state, are each in contact with the end face of the receptacle 5. Only the clamping slot area lies in the pocket of the receptacle 5 in the assembled state. A plug-in pin 13 is connected to each of the projections 12 on the side remote from the clamping slot. The plug-in pin 13 is provided for making electrical contact between the insulation displacement contact 11 and a printed circuit board.

In addition to the receptacles 5, a plug assembly 14 is formed by injection molding on the upper side, in the peripheral region of the stator 1. The plug assembly 14 is thus part of the stator unit 4 and has overmolded contacts 15, which are approximately rectangular and extend in a radial direction to the longitudinal axis 100 and parallel thereto. The contacts 15 project radially beyond the main body of the stator unit 4 and protrude from the overmolded region, so that a plug connection 16 is formed for an external power supply connection. The other free ends of the contacts 15 project upwardly from the overmolded portion, and are provided for connection to a printed circuit board and power supply to a controller disposed on the printed circuit board. These free ends of the contacts 15 have a shoulder 17, which is provided to limit the insertion of the contacts 15 into the printed circuit board.

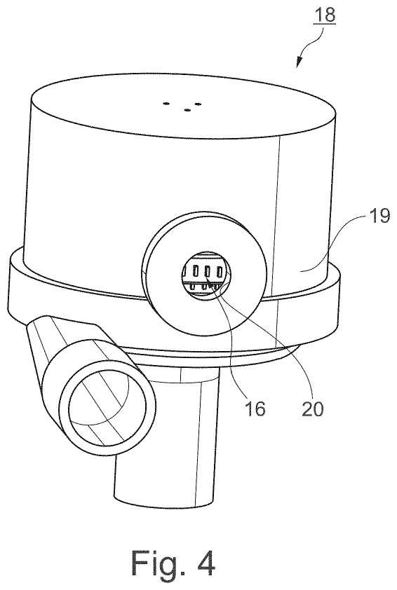

FIG. 4 shows the electric motor 18. In the area of the plug connection 16, the housing of the electric motor 19 has an opening 20 into which the external power supply connection can be inserted and connected to the plug assembly 16 inside.

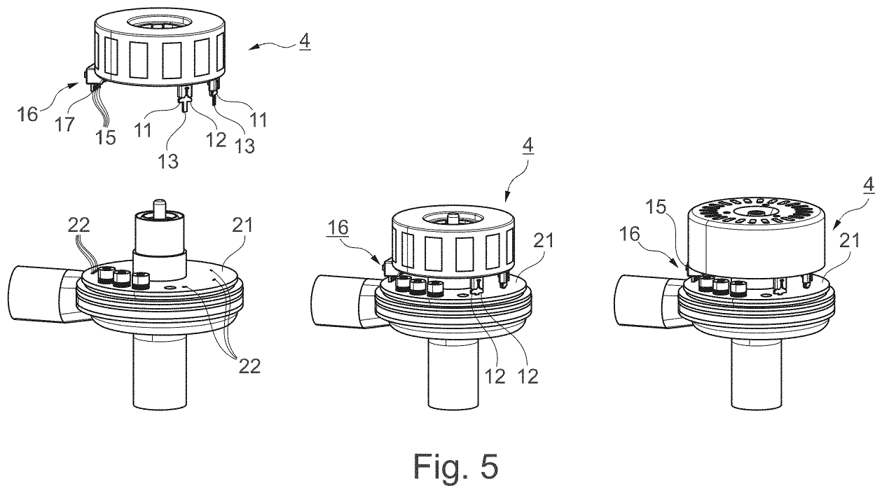

FIG. 5 schematically shows the mounting of the stator unit 4 on the printed circuit board 21. The printed circuit board 21 has penetrating recesses 22 at corresponding locations for receiving the plug-in pins 13 and the contacts of the connector assembly 15. The stator unit 4 is placed centrally above the printed circuit board 21, so that the longitudinal axis of the stator unit 100 and the axis of symmetry of the printed circuit board are congruent. The stator unit 4 is fed in longitudinal direction onto the printed circuit board 21 until the plug pins 13 and the contacts 15 are placed directly above the corresponding recesses 22. Then, the plug pins 13 and the contacts 15 are pressed into the recesses 22. The projections 12 of the insulation displacement contacts 11 of the plug pins also limit the press-fit operation in this direction. The contacts 15 have projections 17 for limiting the press-fit operation in the axial direction. The electrical connection of the printed circuit board 21 to the phase windings is particularly simple due to the insulation displacement contacts incorporated in the stator assembly, and requires a minimum of installation space. The contacts of the plug assembly 15 are contacted with the printed circuit board 21 in the same operation, and can be used to energize the controller. Since the connector assembly 16 is integrally formed when the stator is overmolded, additional components are not required.

The described stator unit 4 is preferably part of a brushless DC motor which in turn is preferably part of a pump, in particular a low wattage auxiliary pump.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. An electric motor, comprising:
a printed circuit board;
a rotor which is mounted rotatably about an axis of rotation; and
a stator circumferentially surrounded by the rotor; wherein
the stator includes stator teeth and coils wound around the stator teeth, the coils are made of from a winding wire with winding wire ends;
the stator is overmolded by an injection molding, a plug assembly being defined on an upper side of the stator;
the plug assembly includes contacts overmolded by the injection molding to define a plug connection of an external power supply connection on one side and to make direct electrical contact with the printed circuit board on another side.

2. The electric motor according to claim 1, wherein the circuit board includes recesses in which free ends of the contacts engage.

3. The electric motor according to claim 1, wherein the contacts are rectangular or approximately rectangular and extend radially toward a longitudinal axis of the stator and parallel thereto.

4. The electric motor according to claim 1, wherein the contacts project radially beyond the stator and project radially from an overmolded region to define the plug connection.

5. The electric motor according to claim 1, wherein the connector assembly supplies current to a controller on the printed circuit board.

6. The electric motor according to claim 2, wherein the free ends of the contacts protrude upwards from an overmolded region and contact the printed circuit board, the free ends including a shoulder to axially limit an insertion depth into the printed circuit board.

7. The electric motor according to claim 1, wherein
receptacles are defined on the upper side of the stator, at least one of the winding wire ends is inserted into each of the receptacles; and
an insulation displacement contact is inserted into the receptacles to make electrical contact with the at least one of the winding wire ends, the insulation displacement contact including a plug-in pin which makes direct electrical contact with the printed circuit board.

8. The electric motor according to claim 7, wherein the circuit board includes recesses into which the plug-in pin is engaged.

9. The electric motor according to claim 7, wherein the winding wire ends are bent outwards in a radial direction and each inserted into a respective one of the receptacles.

10. The electric motor according to claim 1, wherein
the receptacles extend with longitudinal axes thereof parallel or substantially parallel to a longitudinal axis of the stator, and are pocket-shaped and rectangular or substantially rectangular in cross-section with two longitudinal sides and two transverse sides;
each of the pocket-shaped receptacles includes an opening which is located on an upper surface remote from the stator, and the two longitudinal sides extend tangentially from a circumferential direction of the longitudinal axis; and
on the upper surface remote from the stator, the receptacles each include, on one of the two longitudinal side on the inside in a radial direction, an incision which extends parallel or substantially parallel to the longitudinal axis of the stator and into which the at least one winding wire end is inserted.

11. The electric motor according to claim 7, wherein the receptacles are evenly spaced from each other in a circumferential direction and extend collectively over an angular range of less than about 120°.

12. The electric motor according to claim 1, wherein the electric motor includes three phase groups, each of which including two winding wire ends which are inserted into a common one of a total of three of the receptacles and which are electrically contacted by a common one of the insulation displacement contacts.

13. The electric motor according to claim 1, wherein the electric motor includes 10 poles and 12 stator teeth.

14. The electric motor according to claim 1, wherein the winding wire ends are held on the upper side of the stator by a wire holder which is overmolded by the injection molding.

15. The electric motor according to claim 1, wherein the injection molding is made of plastic or resin.

16. An electric pump comprising the electric motor according to claim 1.

17. A method of electrically contacting a stator of an electric motor with a printed circuit board, the stator includes stator teeth and coils wound on the stator teeth, and the coils are made from a winding wire including winding wire ends which extend parallel or substantially parallel to a longitudinal axis of the stator, the method comprises:
a) overmolding the stator by injection molding, to form a connector assembly on an upper side of the stator, the connector assembly including overmolded contacts each including a first free end and a second free end;
b) positioning the stator with respect to the printed circuit board, the printed circuit board and the stator being aligned with their upper and lower sides parallel or substantially parallel to one another and the longitudinal axes of the stator;
c) simultaneously pressing the first free ends of the contacts into recesses of the printed circuit board in the longitudinal direction; and
d) contacting an external power supply terminal with the second free ends of the contacts to energize a controller on the printed circuit board.

18. The method according to claim 17, wherein
in step a), during overmolding of the stator, receptacles are additionally formed on the upper side of the stator;
the method further comprising:
e) bending the winding wire ends outwards in the radial direction to the longitudinal axis of the stator and inserting them into the receptacles; and
f) inserting one insulation displacement contact into one of the receptacles to electrically contact the winding wire ends with the insulation displacement contacts, each of the insulation displacement contacts including a plug-in pin; and
in step c) the plug-in pins of the insulation displacement contacts are pressed into the recesses of the printed circuit board in the longitudinal direction to electrically contact the printed circuit board with the winding wires.

19. The method according to claim 18, wherein
the receptacles extend with their longitudinal axes parallel or substantially parallel to the longitudinal axis of the stator, are pocket-shaped and rectangular or substantially rectangular in cross-section with two longitudinal sides and two transverse sides;
openings of the receptacles are located on an upper surface remote from the stator, and the two longitudinal sides extend tangentially from a circumferential direction of the longitudinal axis;
on the upper surface remote from the stator, the receptacles each include, on one of the two longitudinal side on the inside in a radial direction, an incision defined by a slot which extends parallel or substantially parallel to the longitudinal axis of the stator; and
at least one winding wire end is inserted into the slot.

20. The method according to claim 18, wherein the receptacles are evenly spaced from each other in a circumferential direction and extend together over an angular range of less than about 120°.

21. The method according to claim 17, wherein the electric motor includes three phase groups, each of the phase groups including two of the winding wire ends which are inserted into a common one of the receptacles and which are electrically contacted by a common one of the insulation displacement contacts.

22. The method according to claim 17, wherein the electric motor includes 10 poles and 12 stator teeth.

23. The method according to claim 17, wherein the winding wire ends are held on the upper side of the stator by a wire holder which is overmolded in the injection molding process of step a).

24. The method according to claim 17, wherein the injection molding process in step a) is carried out with plastic or resin.
